(19) United States
(12) Patent Application Publication
(10) Pub. No.: US 2018/0054891 A1
(43) Pub. Date: Feb. 22, 2018

(54) PRINTED WIRING BOARD AND METHOD FOR MANUFACTURING PRINTED WIRING BOARD

(71) Applicant: IBIDEN CO., LTD., Ogaki (JP)

(72) Inventors: Teruyuki ISHIHARA, Ogaki (JP); Hiroyuki BAN, Ogaki (JP); Haiying MEI, Ogaki (JP)

(73) Assignee: IBIDEN CO., LTD., Ogaki (JP)

(21) Appl. No.: 15/682,770

(22) Filed: Aug. 22, 2017

(30) Foreign Application Priority Data
Aug. 22, 2016 (JP) 2016-161868

(51) Int. Cl. H05K 1/11; H05K 1/02; H05K 1/03; H05K 1/18; H05K 3/02; H05K 3/06; H05K 3/46; H05K 3/40

(52) U.S. Cl. CPC H05K 1/113; H05K 1/0298; H05K 1/0313; H05K 3/4007; H05K 3/025; H05K 3/06; H05K 3/465; H05K 1/181

(57) ABSTRACT

A printed wiring board includes a support plate, a laminate formed on the support plate and including first conductor pads on first surface side of the laminate and second conductor pads on second surface side of the laminate, and a solder resist layer interposed between the support plate and laminate and having openings formed such that the openings are exposing the first pads. The laminate includes a resin insulating layer and has a first surface on the first surface side and a second surface on the second surface side on the opposite side, and a via conductor structure penetrating from the first surface to the second surface of the laminate such that the via structure includes via conductors formed in the insulating layer and tapering from the first surface side toward second surface side of the laminate, and the second pads are protruding from the second surface of the laminate.

### CROSS-REFERENCE TO RELATED APPLICATIONS

The present application is based upon and claims the benefit of priority to Japanese Patent Application No. 2016-161868, filed Aug. 22, 2016, the entire contents of which are incorporated herein by reference.

### BACKGROUND OF THE INVENTION

### Field of the Invention

The present invention relates to a printed wiring board having a support plate and relates to a method for manufacturing the printed wiring board.

### Description of Background Art

Japanese Patent Laid-Open Publication No. 2009-224739 describes a multilayer wiring board that does not have a core substrate. The multilayer wiring board is formed from only wiring patterns such as connection pads and an insulating layer and a protective film. The multilayer wiring board has a mounting surface for a semiconductor element and a connection surface for external connection terminals on the opposite side of the mounting surface. Wiring patterns on the connection surface side for external connection terminals are embedded in an insulating layer. The entire contents of this publication are incorporated herein by reference.

### SUMMARY OF THE INVENTION

According to one aspect of the present invention, a printed wiring board includes a support plate, a laminate formed on the support plate and including first conductor pads on a first surface side of the laminate and second conductor pads on a second surface side of the laminate, and a solder resist layer interposed between the support plate and the laminate and having openings formed such that the openings are exposing the first conductor pads respectively. The laminate includes a resin insulating layer and has a first surface on the first surface side and a second surface on the second surface side on the opposite side with respect to the first surface of the laminate, and a via conductor structure penetrating from the first surface to the second surface of the laminate such that the via conductor structure includes via conductors formed in the resin insulating layer and tapering from the first surface side toward the second surface side of the laminate, and the second conductor pads are protruding from the second surface of the laminate respectively.

According to another aspect of the present invention, a method for manufacturing a printed wiring board includes forming a plating resist layer on a metal foil provided on a base plate such that the plating resist layer has openings positioned for conductor pads, forming a conductor film in the openings of the plating resist such that a conductor layer including the conductor pads is formed on the metal foil, laminating, on the conductor layer, at least one set of a resin insulating layer and a conductor layer, such that a laminate including the conductor layers and resin insulating layer is formed to have a first surface and a second surface on a metal foil side on the opposite side with respect to the first surface, forming a solder resist layer on the first surface of the laminate, positioning a support plate on the first surface of the laminate such that the solder resist layer is interposed between the laminate and the support plate, removing the base plate from the laminate, removing the metal foil on the laminate such that the plating resist layer is exposed, and removing the plating resist from the laminate.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a printed wiring board according to an embodiment of the present invention.

FIG. 2 is an enlarged view of a modified embodiment of second conductor pads of the printed wiring board of FIG. 1;

FIG. 3 is a cross-sectional view of a printed wiring board according to another embodiment of the present invention;

FIG. 4 illustrates a printed wiring board according to an embodiment of the present invention in which an electronic component is mounted;

FIG. 5A illustrates an example of a base plate in a method for manufacturing a printed wiring board according to an embodiment of the present invention;

FIG. 5B illustrates an example of formation of a conductor layer on the base plate in a method for manufacturing a printed wiring board according to an embodiment of the present invention;

FIG. 5C illustrates an example of formation of a laminate in a method for manufacturing a printed wiring board according to an embodiment of the present invention;

FIG. 5D illustrates an example of the formation of the laminate in a method for manufacturing a printed wiring board according to an embodiment of the present invention;

FIG. 5E illustrates an example of the formation of the laminate in a method for manufacturing a printed wiring board according to an embodiment of the present invention;

FIG. 5F illustrates an example of the formation of the laminate in a method for manufacturing a printed wiring board according to an embodiment of the present invention;

FIG. 5G illustrates an example of the formation of the laminate in a method for manufacturing a printed wiring board according to an embodiment of the present invention;

FIG. 5H illustrates an example of formation of a solder resist layer in a method for manufacturing a printed wiring board according to an embodiment of the present invention;

FIG. 5I illustrates an example of a process of providing a support plate in a method for manufacturing a printed wiring board according to an embodiment of the present invention;

FIG. 5J illustrates an example of removal of the base plate in a method for manufacturing a printed wiring board according to an embodiment of the present invention;

FIG. 5K illustrates an example of removal of a metal foil in a method for manufacturing a printed wiring board according to an embodiment of the present invention;

FIG. 5L illustrates an example of removal of a plating resist layer in a method for manufacturing a printed wiring board according to an embodiment of the present invention;

FIG. 5M illustrates an example of mounting an electronic component in a method for manufacturing a printed wiring board according to an embodiment of the present invention;

FIG. 5N illustrates an example of removal of the support plate in a method for manufacturing a printed wiring board according to an embodiment of the present invention;

FIG. 6 is a cross-sectional view of a printed wiring board of another embodiment of the present invention;

FIG. 7 illustrates a printed wiring board according to an embodiment of the present invention in which an electronic component is mounted;

FIG. 8A illustrates an example of a formation process of conductor posts in a method for manufacturing a printed wiring board according to an embodiment of the present invention;

FIG. 8B illustrates an example of the formation process of the conductor posts in a method for manufacturing a printed wiring board according to an embodiment of the present invention;

FIG. 8C illustrates an example of removal of a metal foil in a method for manufacturing a printed wiring board according to an embodiment of the present invention;

FIG. 8D illustrates an example of removal of a plating resist layer in a method for manufacturing a printed wiring board according to an embodiment of the present invention;

FIG. 8E illustrates an example of mounting an electronic component in a method for manufacturing a printed wiring board according to an embodiment of the present invention; and

FIG. 8F illustrates an example of removal of a support plate in a method for manufacturing a printed wiring board according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

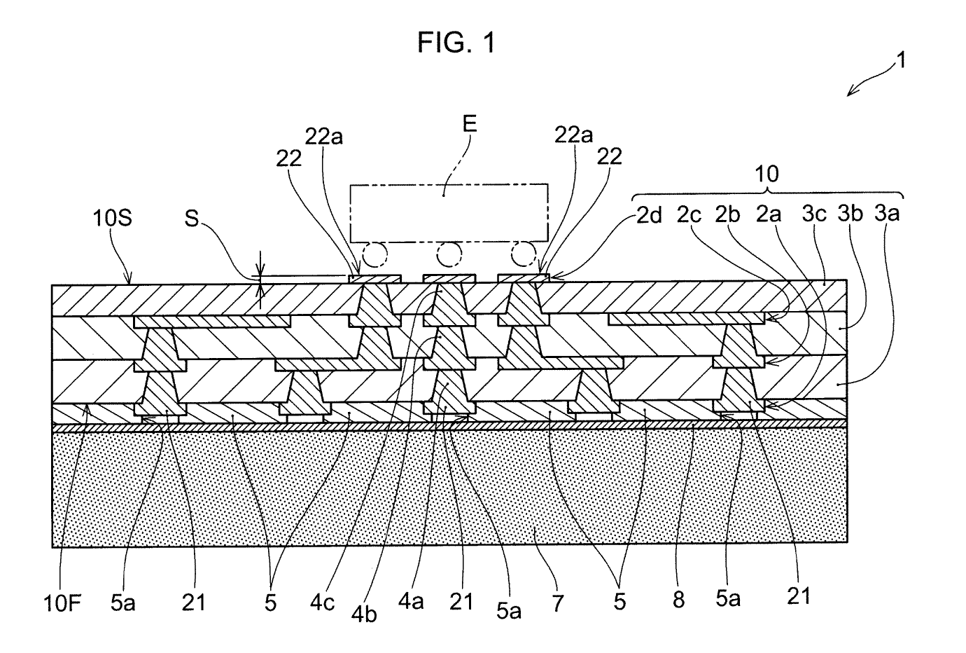

FIG. 1 illustrates a cross-sectional view of an example of a printed wiring board 1 of the embodiment. The printed wiring board 1 includes a laminate 10 of conductor layers and resin insulating layers, the laminate 10 having a first surface (10F) that is a surface of a laminated resin insulating layer, and a second surface (10S) that is on the opposite side of the first surface (10F). The printed wiring board 1 further includes a solder resist layer 5 formed on the first surface (10F) of the laminate 10, and a support plate 7 provided on the first surface (10F) of the laminate 10 with the solder resist layer 5 sandwiched therebetween. The laminate 10 includes one or more resin insulating layers (in the example of FIG. 1, a first resin insulating layer (3a), a second resin insulating layer (3b), and a third resin insulating layer (3c)) and two or more conductor layers (in the example of FIG. 1, a first conductor layer (2a), a second conductor layer (2b), a third conductor layer (2c), and a fourth conductor layer (2d)) laminated with the resin insulating layers sandwiched therebetween. The first surface (10F) of the laminate 10 is formed from a surface of a resin insulating layer (the first resin insulating layer (3a) in the example of FIG. 1) exposed on one side in a lamination direction of the laminate 10. And, the second surface (10S) of the laminate 10 is formed from a surface of a resin insulating layer (the third resin insulating layer (3c) in the example of FIG. 1) exposed on the other side in the lamination direction of the laminate 10.

The laminate 10 has a laminated structure similar to that of a so-called build-up part in a build-up wiring board. In the laminate 10 of FIG. 1, the conductor layers and the resin insulating layers are alternately laminated in the order of, from the first surface (10F) side, the first conductor layer (2a), the first resin insulating layer (3a), the second conductor layer (2b), the second resin insulating layer (3b), the third conductor layer (2c), the third resin insulating layer (3c), and the fourth conductor layer (2d). The laminate 10 of the printed wiring board of the embodiment is not limited to the example of FIG. 1, but can be formed by any number of conductor layers and any number of resin insulating layers. For example, the laminate 10 may include only one resin insulating layer and conductor layers that are respectively provided on both sides the resin insulating layer, or may include more than four conductor layers. Further, it is also possible that the laminate 10 is formed by laminating some conductor layers and some resin insulating layers at one time rather than forming the conductor layers and the resin insulating layers one by one as in a build-up wiring board.

The conductor layers in the laminate 10 are each formed of, for example, a good conductive material such as copper. The resin insulating layers in the laminate 10 are not particularly limited as long as the resin insulating layers are insulating and each have adhesion to a conductor layer, an appropriate thermal expansion coefficient, and the like. For example, an epoxy resin can be used for the formation of the resin insulating layers.

The conductor layers in the laminate 10 each have conductor patterns formed by patterning conductor pads, wirings and the like into predetermined shapes. In the example of FIG. 1, the laminate 10 has multiple first conductor pads 21 formed on the first surface (10F) and multiple second conductor pads 22 formed on the second surface (10S). The first conductor pads 21 are formed in the first conductor layer (2a) that is positioned on the most first surface (10F) side among the conductor layers of the laminate 10. The second conductor pads 22 are formed in the fourth conductor layer (2d) that is positioned on the most second surface (10S) side among the conductor layers of the laminate 10.

The second conductor pads 22 can be connected to an external electrical circuit. For example, an electronic component (E) or an external wiring board (not illustrated in the drawings) is connected to the second conductor pads 22. Examples of the electronic component (E) include a bare chip of a semiconductor element, a WLP, and integrated circuit devices of other forms. Examples of the external wiring board include a wiring board of a package of an external electronic component, a motherboard of an electrical device in which the printed wiring board 1 is used, and the like.

The support plate 7 is formed of a rigid material, and supports the laminate 10 such that warpage or deflection of the printed wiring board 1 can be suppressed. The support plate 7 is formed of, for example, a metal plate, a glass epoxy plate obtained by impregnating a reinforcing material such as glass fiber with an epoxy resin, or a double-sided copper-clad laminated plate having a copper foil on both sides of a glass epoxy substrate, or the like. Besides these, any appropriately rigid material can be used for the support plate 7. The support plate 7 has a thickness of, for example, 100 μm or more and 500 μm or less. The laminate 10 is properly supported and the printed wiring board 1 including the support plate 7 does not become extremely thick. The support plate 7 is adhered to the solder resist layer 5 by an adhesive that forms the adhesive layer 8.

A material that forms the adhesive layer 8 is not particularly limited as long as the material can closely adhere to the support plate 7 and the solder resist layer 5. As will be described later, when a part of the support plate 7 or the entire support plate 7 is removed during use of the printed wiring board 1, a material that has moderate adhesion but does not develop a strong adhesive force with respect to the solder resist layer 5 and the first conductor layer (2a) is preferred as the material of the adhesive layer 8. A material at least capable of developing a stronger adhesive force with respect to the support plate 7 than with respect to the solder resist layer 5 and the first conductor layer (2a) is preferred as the material of the adhesive layer 8. It is also possible that the material that forms the adhesive layer 8 is a material that loses adhesiveness with respect to the solder resist layer 5 and the first conductor layer (2a) due to a specific treatment such as ultraviolet irradiation or heating. For example, an acrylic resin can be used as the material of the adhesive layer 8.

In the printed wiring board 1 of the embodiment, the support plate 7 is provided on the first surface (10F) of the laminate 10. Therefore, warpage or deflection of the printed wiring board 1 is suppressed. For example, when the electronic component (E) is mounted on the second conductor pads 22, multiple electrodes of the electronic component (E) can be respectively substantially uniformly brought close to the multiple second conductor pads 22. The electrodes of the electronic component (E) are unlikely to float from the second conductor pads 22. Since flatness of the second surface (10S) of the laminate 10 is maintained, positional deviation of the electronic component (E) is unlikely to occur. The electronic component (E) is properly mounted with a good yield. Further, since the printed wiring board 1 is unlikely to deflect, in such a component mounting process or in a manufacturing process of the printed wiring board 1 itself, the printed wiring board 1 can be easily handled.

As will be described later, the support plate 7 can be provided on the first surface (10F) after the conductor layers and the resin insulating layers in the laminate 10 are formed. Therefore, the support plate 7 can be attached to the laminate 10, for example, after performing an energization inspection of an electrical circuit (not illustrated in the drawings) formed by conductor patterns of the conductor layers. That is, it is possible to provide a support plate 7 only for a laminate 10 that is determined to be non-defective by an energization inspection. Then, the electronic component (E) can be mounted on the laminate 10 that is supported by the support plate 7 and has proper energizing performance.

As illustrated in FIG. 1, in the printed wiring board 1 of the embodiment, the second conductor pads 22 protrude on the second surface (10S) of the laminate 10. That is, a surface (22a) of each of the second conductor pads 22 on the opposite side of the support plate 7 is not flush with the second surface (10S) of the laminate 10, but is positioned on an upper side of the second surface (10S) (on a farther side of the second surface (10S) from the support plate 7). For example, even when an electronic component having a package such as an LGA (Land Grid Array) having terminals formed substantially coplanar with a surface of a resin sealing portion is mounted, the terminals of the electronic component and the second conductor pads 22 can be substantially reliably brought into contact with each other. This is because that, even when surfaces of the terminals of the electronic component are recessed from the surface of the resin-sealed portion due to manufacturing variation or the like, contact between the terminals of the electronic component and the second conductor pads 22 is unlikely to be blocked by contact between the resin sealing portion of the electronic component and the third resin insulating layer (3c).

Further, solder supplied on the surfaces (22a) of the second conductor pads 22 does not directly wet spread toward adjacent second conductor pads 22, but first flows down from the surfaces (22a) toward the second surface (10S) of the laminate 10. A short-circuit defect is unlikely to occur between adjacent second conductor pads 22. In the example of FIG. 1, the second surface (10S) of the laminate 10 is exposed without being covered by a solder resist. In this way, even when a solder resist layer is not formed on the second surface (10S) and even when the second conductor pads 22 are arrayed at a fine pitch, an electronic component or the like can be connected with good quality on the second surface (10S). As will be described later, according to a method for manufacturing the printed wiring board of the embodiment, the fourth conductor layer (2d) including the second conductor pads 22 can be formed, for example, by electroplating only without etching. Therefore, the second conductor pads 22 can be formed at a fine pitch. Therefore, the structure of the printed wiring board 1 that can suppress a short-circuit defect by having the second conductor pads 22 protruding from the second surface (10S) of the laminate 10 is particularly beneficial.

A protruding length of the second conductor pads 22 from the second surface (10S) of the laminate 10, that is, a distance (S) between the surface (22a) of each of the second conductor pads 22 and the second surface (10S) of the laminate 10, is 5 μm or more and 30 μm or less. Effects such as reliable contact with the electronic component (E) and suppression of a short-circuit defect can be sufficiently obtained. In addition, a height after the electronic component (E) is mounted does not become extremely high. The protruding length (distance (S)) of the second conductor pads 22 can be easily adjusted, for example, as will be described later, by adjusting a length of a plating time when the second conductor pads 22 are formed by electrolytic plating.

As illustrated in FIG. 1, the laminate 10 further has multiple via conductors (in the example of FIG. 1, first via conductors (4a), second via conductors (4b), and third via conductors (4c)) that each penetrate one of the first-third resin insulating layers (3a-3c). The first via conductors (4a) electrically connect the conductor patterns (for example, the first conductor pads 21) in the first conductor layer (2a) and the conductor patterns in the second conductor layer (2b). Similarly, the second via conductors (4b) connect the conductor patterns in the second conductor layer (2b) and the conductor patterns in the third conductor layer (2c); and the third via conductors (4c) connect the conductor patterns in the third conductor layer (2c) and the conductor patterns (for example, the second conductor pads 22) in the fourth conductor layer (2d). The via conductors are preferably formed of the same material as the first-fourth conductor layers (2a-2d).

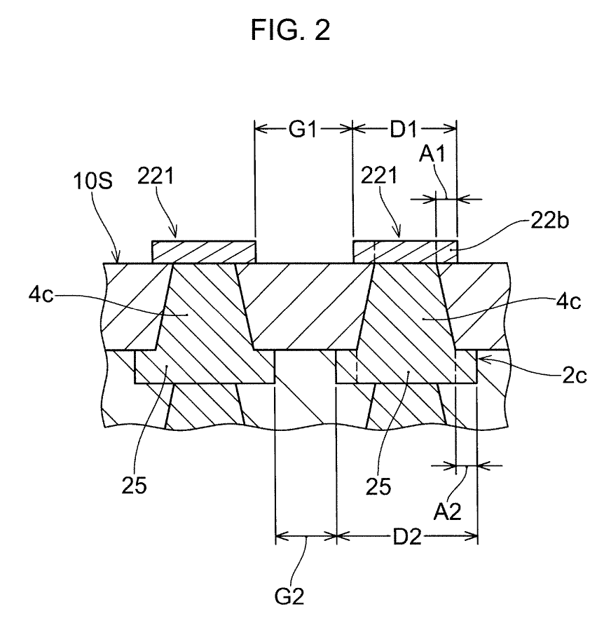

The first-third via conductors (4a-4c) are each gradually reduced in diameter from the first surface (10F) side of the laminate 10 toward the second surface (10S) side of the laminate 10. That is, a size of a cross section of each of the via conductors in a plane orthogonal to a thickness direction of the laminate 10 is larger closer to the first surface (10F) side and smaller closer to the second surface (10S) side. Therefore, of each of the via conductors, an end surface on second surface (10S) side is smaller than an end surface on the first surface (10F) side. Even when formation positions of the via conductors vary to some extent when the printed wiring board 1 is manufactured, the end surfaces of the via conductors on the second surface (10S) side can fit within small regions on the second surface (10S) side. Therefore, the conductor patterns on the second surface (10S) side of the laminate 10 connected to the via conductors can be reduced in size. As an example, FIG. 2 illustrates a modified embodiment 221 of the second conductor pads 22.

As illustrated in FIG. 2, due to the third via conductors (4c), second conductor pads 221 on the second surface (10S) of the laminate 10 and conductor pads 25 of the third conductor layer (2c) on the opposite side of the second surface (10S) are connected to each other. The second conductor pads 221 each include an outer edge portion (annular ring) (22b) for preparing for variations in the positions of the third via conductors (4c). A width (A1) of the outer edge portion (22b) is the same as a width (A2) of an outer edge portion of each of the conductor pads 25. However, an end surface of each of the third via conductors (4c) on the second surface (10S) side is smaller than an end surface on the first surface (10F) side. Therefore, as illustrated in FIG. 2, a width (D1) of each of the second conductor pads 221 can be smaller than a width (D2) of each of the conductor pads 25. Along with this, a gap (G1) between adjacent second conductor pads 221 can be larger than a gap (G2) between adjacent conductor pads 25. In the second conductor pads 221 that can be connected to an external electrical circuit, occurrence of a short-circuit defect due to flow of solder or the like can be suppressed. Further, it is also possible to array the second conductor pads 221 at a fine pitch.

In this way, since the third via conductors (4c) are each reduced in diameter toward the second surface (10S) side of the laminate 10, it is possible to suppress occurrence of a short-circuit defect and to array the second conductor pads 22 at a fine pitch. As described above, also in a manufacturing method aspect, the second conductor pads 22 can be formed at a fine pitch. Therefore, the structure of the printed wiring board 1 having the via conductors that are each reduced in diameter toward the second surface (10S) side of the laminate 10 is particularly beneficial. The term “reduced in diameter” is used for convenience only, and a cross-sectional shape of each of the via conductors is not limited to a circle or an ellipse.

The first conductor pads 21 formed on the first surface (10F) of the laminate 10 are not embedded in the first resin insulating layer (3a) that forms the first surface (10F) of the laminate 10, but are formed on the first surface (10F). In the example of FIG. 1, the first conductor pads 21 protrude on the first surface (10F). The first conductor pads 21 can also be connected to an external electrical circuit such as an electronic component or a motherboard. Since the first conductor pads 21 protrude on the first surface (10F), similar to the above description about the second conductor pads 22, terminals of an electronic component and the first conductor pads 21 can be substantially reliably brought into contact with each other. Further, a short-circuit defect is unlikely to occur between adjacent first conductor pads 21. As illustrated in FIG. 1, the printed wiring board 1 has the solder resist layer 5 on the first surface (10F) of the laminate 10. Therefore, in connection between the first conductor pads 21 and an external electrical circuit, occurrence of a short-circuit defect due to solder or the like between the first conductor pads 21 is further suppressed. Since the first via conductors (4a) are each reduced in diameter toward the second surface (10S) side, a width of each of the first conductor pads 21 can be larger than a width of each of the conductor pads on the second surface (10S) side. However, since the solder resist layer 5 is formed on the first surface (10F), a risk of occurrence of a short-circuit defect is reduced.

When the first conductor pads 21 are connected to an external electrical circuit, before the connection, the support plate 7 can be removed. Or, it is also possible that only predetermined first conductor pads 21 to be connected to an external electrical circuit are exposed. As described above, the support plate 7 is preferably adhered to the solder resist layer 5 via the adhesive layer 8 that does not develop a strong adhesive force between the support plate 7 and the solder resist layer 5. When necessary, the support plate 7 can be easily removed.

In the example of FIG. 1, the solder resist layer 5 is formed between the first conductor pads 21. The solder resist layer 5 has the openings (5a) on the first conductor pads 21. The solder resist layer 5 covers edges of the first conductor pads 21, and in each of the openings (5a), a central portion of a first conductor pad 21 is exposed. Due to the solder resist layer 5 formed between the first conductor pads 21, a short-circuit defect between the first conductor pads 21 is prevented with a high probability. The solder resist layer 5 can be formed, for example, of a photosensitive epoxy resin or polyimide resin.

In this way, in the present embodiment, a short-circuit defect due to solder or the like can be suppressed on both the surface on one side (for example, the first surface (10F) of the laminate 10) and the surface on the other side (for example, the second surface (10S) of the laminate 10) of the printed wiring board 1. Further, the second conductor pads 22 and an external electrical circuit can be connected on the printed wiring board 1 having good flatness by being supported by the support plate 7. An electrical device using the printed wiring board 1 of the embodiment and having high connection quality can be obtained.

Although not illustrated in the drawings, it is also possible that the support plate 7 and the adhesive layer 8 are provided with openings that communicatively connect with the openings (5a) of the solder resist layer 5 and expose the first conductor pads 21. When an energization inspection of the printed wiring board 1 is performed after the support plate 7 is bonded, it is possible that ease of the energization inspection and defect detection performance are improved. Further, it is also possible that the connection between the first conductor pads 21 and the external electrical circuit is facilitated. In this case, the support plate 7 is preferably an electrical insulator.

It is also possible that, in addition to the second conductor pads 22, multiple third conductor pads are provided on the second surface (10S) of the laminate 10. The multiple third conductor pads may have an array pitch and/or a size different from those of the multiple second conductor pads 22. Further, the third conductor pads may be provided for connecting to an external element other an electronic component or the like connected to the second conductor pads 22.

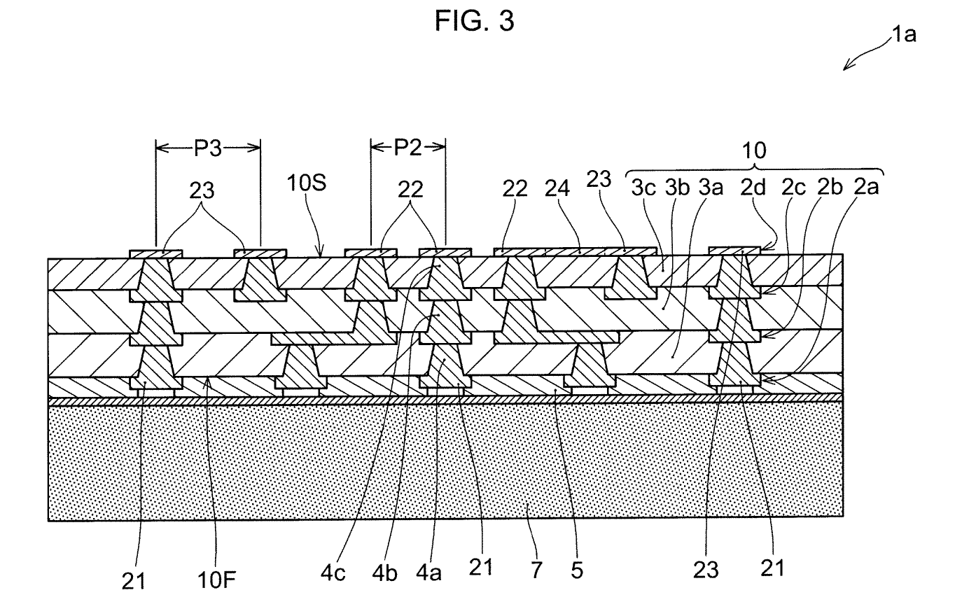

FIG. 3 illustrates a printed wiring board (1a) of another example of the embodiment, the printed wiring board (1a) having multiple third conductor pads 23. The printed wiring board (1a) has the same structure as the printed wiring board 1 of FIG. 1 except that the third conductor pads 23 are provided and that, for connecting to the third conductor pads 23, the third and fourth conductor layers (2c, 2d) include conductor patterns different from those of FIG. 1. A structural element that is the same as in the printed wiring board 1 is indicated using the same reference numeral symbol as in FIG. 1, and description about the structural element is omitted.

As illustrated in FIG. 3, the third conductor pads 23 are formed on an outer peripheral side of the second surface (10S) of the laminate 10 than the multiple second conductor pads 22 that are formed in a central portion of the second surface (10S). The multiple third conductor pads 23 can be formed, for example, over the entire circumference of the multiple second conductor pads 22 so as to surround the second conductor pads 22. Further, it is also possible that the multiple third conductor pads 23 are formed only on both sides of the second conductor pads 22 in one direction along the second surface (10S) (for example, a left-right direction in FIG. 3).

The third conductor pads 23 of the printed wiring board (1a), together with the second conductor pads 22, are formed in the fourth conductor layer (2d). Therefore, similar to the second conductor pads 22, the third conductor pads 23 protrude on the second surface (10S) of the laminate 10. A protruding length of the third conductor pads 23 from the second surface (10S) is substantially the same as the protruding length of the second conductor pads 22 from the second surface (10S). Occurrence of short-circuit defects between the third conductor pads 23 and between the second conductor pads 22 and the third conductor pads 23 is suppressed. Further, the third conductor pads 23 and an external electronic component or the like mounted on the third conductor pads 23 can be reliably brought into contact with each other.

In the printed wiring board (1a) of FIG. 3, some of the second conductor pads 22 and some of the third conductor pads 23 are connected by wiring patterns 24. Similar to the second and third conductor pads (22, 23), the wiring patterns 24 are also formed in the fourth conductor layer (2d). Therefore, the wiring patterns 24 also protrude from the second surface (10S) of the laminate 10 with a protruding length that is substantially the same as the protruding length of the second and third conductor pads (22, 23) from the second surface (10S). As in the example of FIG. 3, by providing the wiring patterns 24 in the fourth conductor layer (2d), the second conductor pads 22 and the third conductor pads 23 can be connected with short paths without passing through other conductor layers or via conductors. In the printed wiring board (1a) illustrated in FIG. 3, any number of the second conductor pads 22 and any number of the third conductor pads 23 can be connected by the wiring patterns of the fourth conductor layer (2d).

As illustrated in FIG. 3, the multiple second conductor pads 22 and the multiple third conductor pads 23 respectively have array pitches (P2, P3). In the example of FIG. 3, the array pitch (P2) of the second conductor pads 22 is smaller than the array pitch (P3) of the third conductor pads 23.

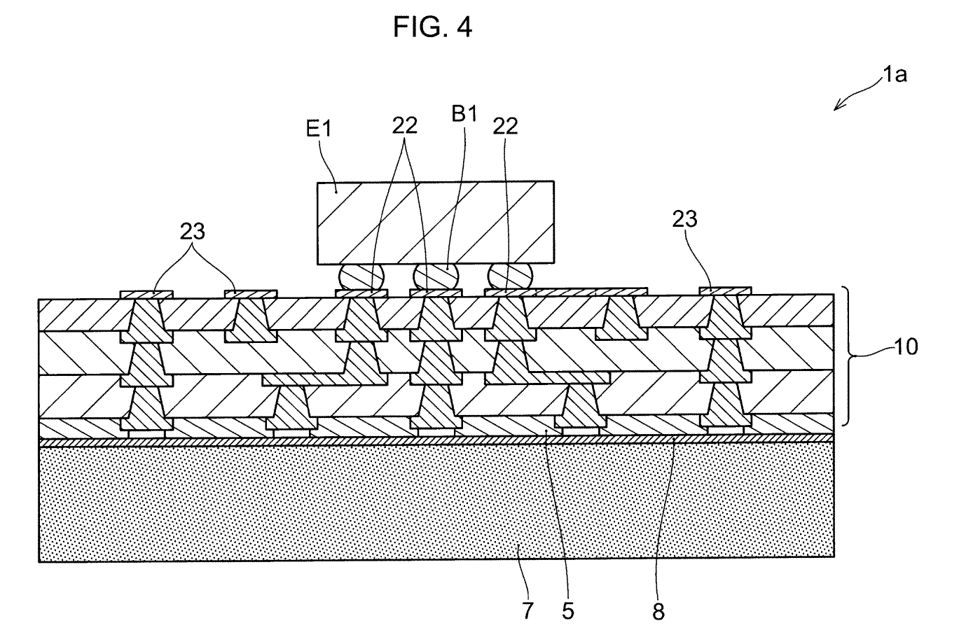

FIG. 4 illustrates an example of a printed wiring board having an electronic component. In the example of FIG. 4, an electronic component (E1) having multiple connection pads (not illustrated in the drawings) arrayed at substantially the same pitch as the second conductor pads 22 of the laminate 10 is mounted on the printed wiring board (1a) of FIG. 3. The connection pads (not illustrated in the drawings) of the electronic component (E1) are connected to the second conductor pads 22 via conductive members (B1) provided on the connection pads. Examples of the conductive members (B1) illustrated in FIG. 4 include solder balls and solder bumps. The conductive members (B1) are not limited to these examples, and can be formed of any other conductive material. Similar to the electronic component (E) of FIG. 1, the electronic component (E1) may be any integrated circuit device such as a bare chip of a semiconductor element, a passive component, or an external wiring board, or the like.

The third conductor pads 23 illustrated in FIG. 4 are not yet connected to an external element, but may be connected to any external element such as an electronic component different from the electronic component (E1). A BGA or the like having a large size has connection pads that are arrayed at a relatively large pitch, and a CSP, a bare chip or the like having a small size has connection pads that are array at a relatively small pitch. For example, a semiconductor element (not illustrated in the drawings) or the like of a CSP or bare chip type is mounted as the electronic component (E1) on the second conductor pads 22. Then, a BGA (not illustrated in the drawings) or the like having terminals only on an outer peripheral portion thereof may be mounted on the third conductor pads 23 having a larger pitch than the second conductor pads 22 in a manner straddling over the electronic component (E1). An electronic component of a package-on-package type including multiple semiconductor devices or the like that are hierarchically mounted can be formed. In this way, in the printed wiring board (1a), electronic components can be mounted at a high density.

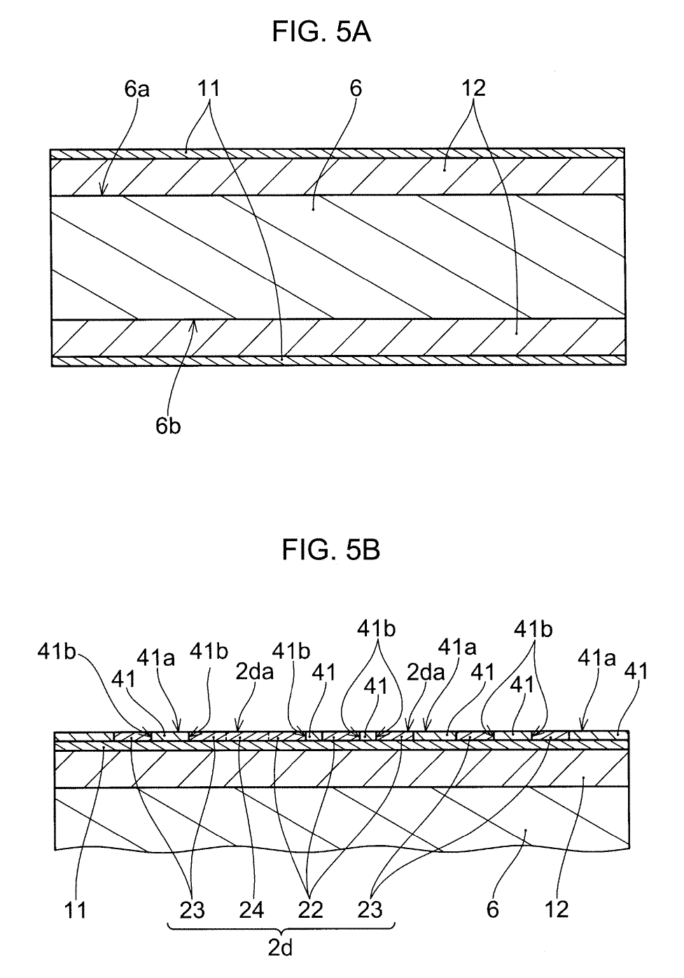

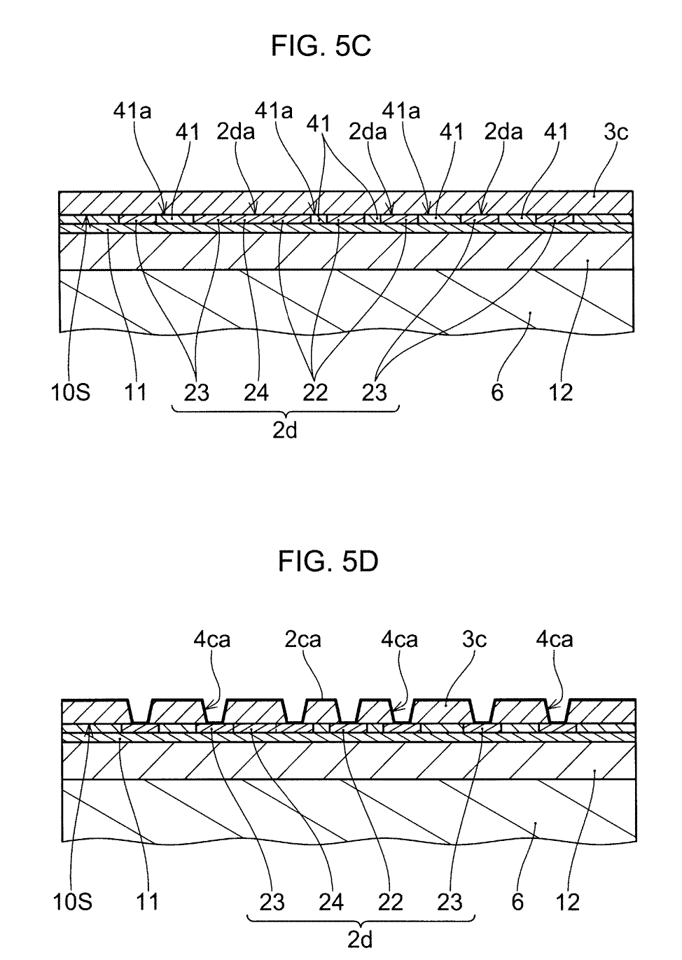

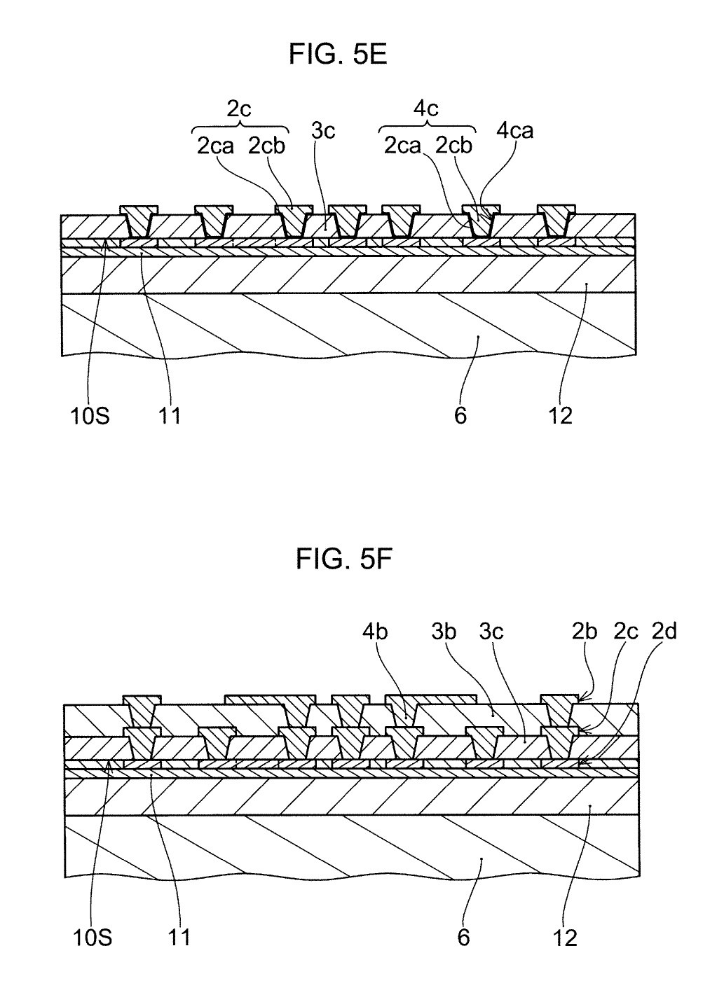

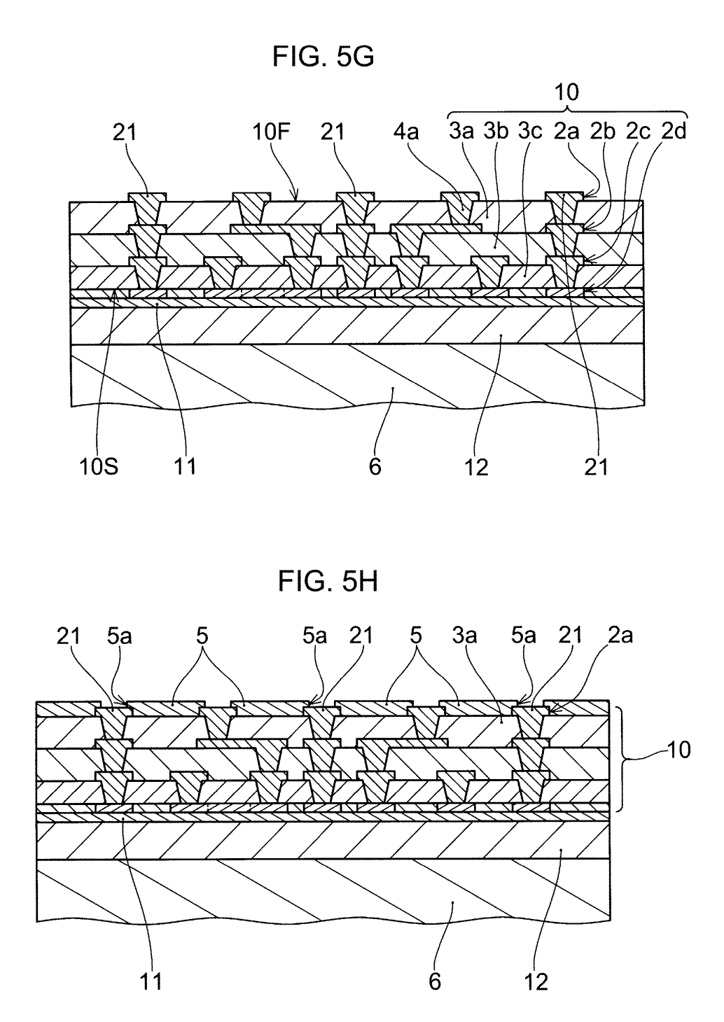

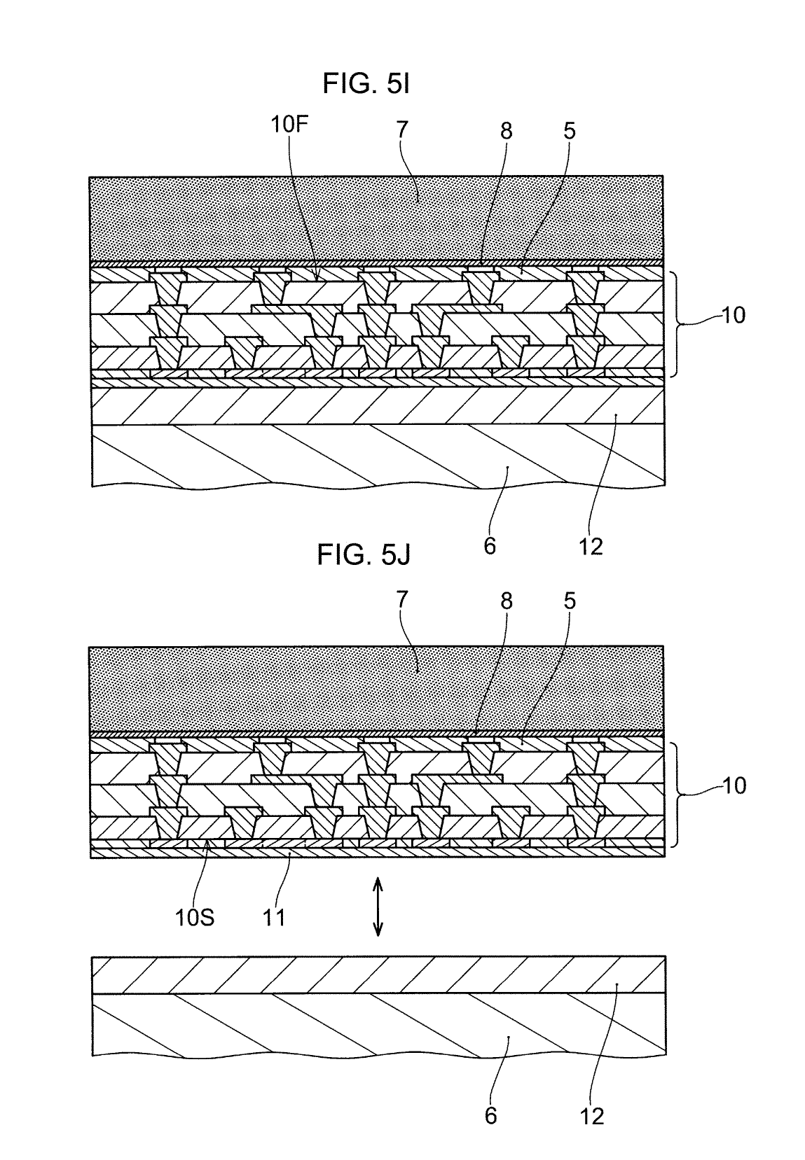

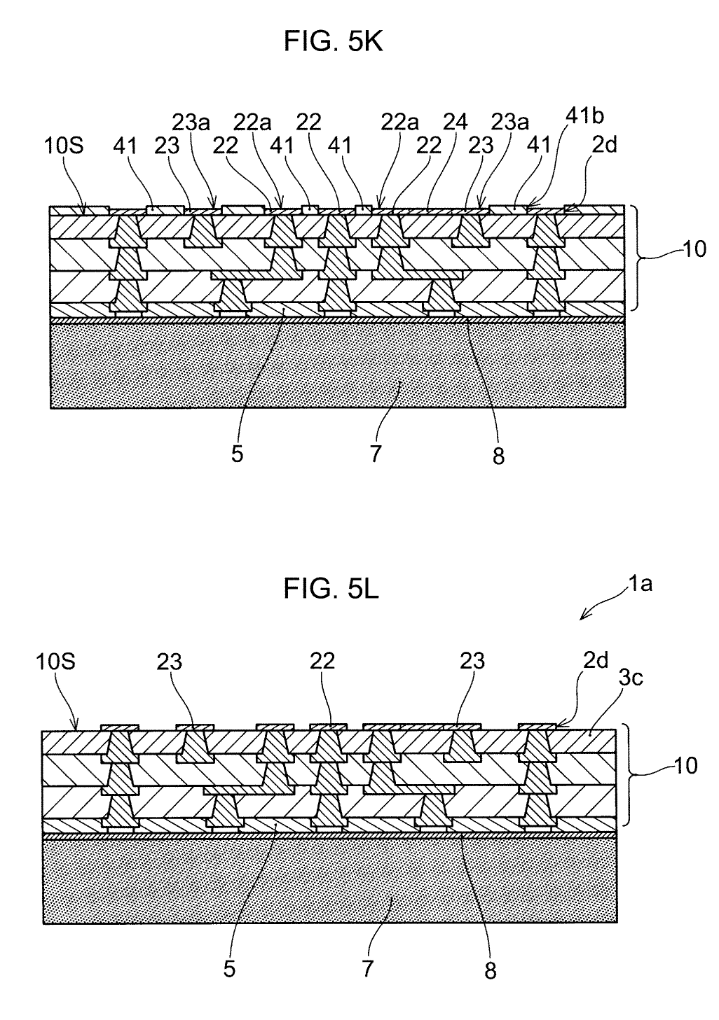

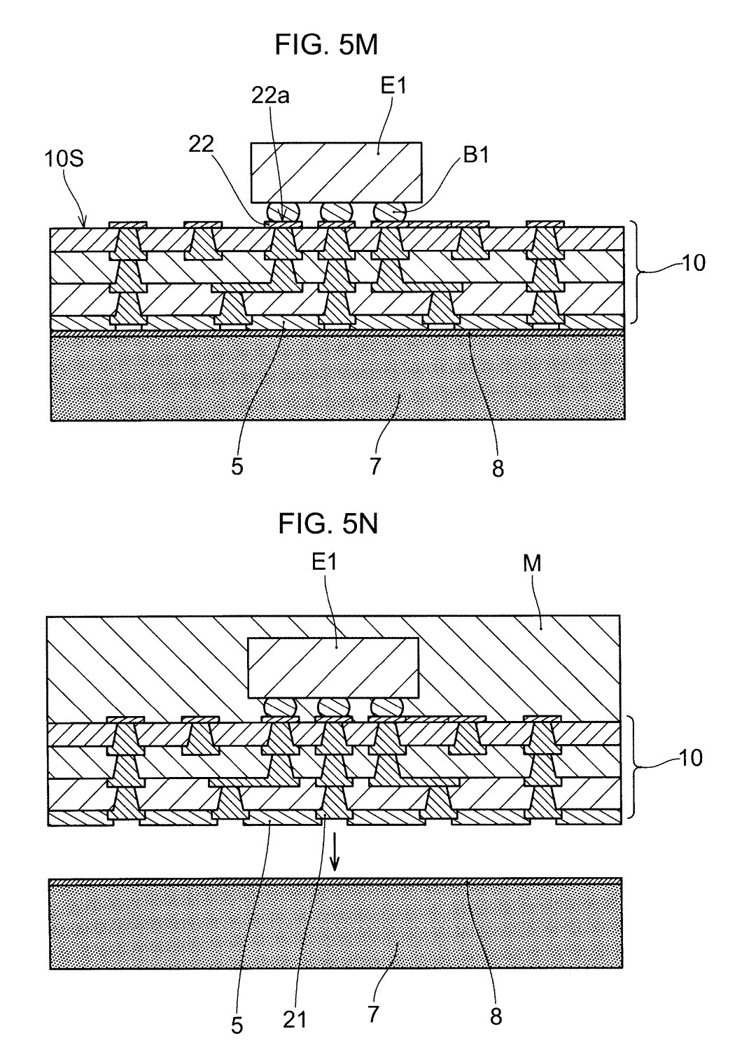

An example of a method for manufacturing a printed wiring board of the embodiment is described below with reference to FIG. 5A-5N using the printed wiring board (1a) illustrated in FIG. 3 as an example.

As illustrated in FIG. 5A, a base plate 6 is prepared, a metal foil 11 being provided on each surface of the base plate 6. The metal foil 11 has a carrier metal foil 12 adhered to one side of the metal foil 11. A surface of the carrier metal foil 12 on the opposite side of the metal foil 11 is bonded to a surface of the base plate 6 by thermocompression bonding. The metal foil 11 and the carrier metal foil 12 are adhered to each other by, for example, a separable adhesive such as a thermoplastic adhesive. It is also possible that the metal foil 11 and the carrier metal foil 12 are adhered to each other only in a margin portion near an outer periphery. A prepreg obtained, for example, by impregnating a core material such as a glass fiber with a resin material such as an epoxy resin is used for the base plate 6. The prepreg can be fully cured when being thermocompression-bonded to the carrier metal foil 12. It is also possible that a metal plate such as copper plate is used for the base plate 6. Further, it is also possible that a double-sided copper-clad laminated plate is used as the base plate 6 having the carrier metal foil 12. The metal foil 11 and the carrier metal foil 12 are preferably copper foils. Other metal foils such as a nickel foil may also be used. The metal foil 11 has a thickness of, for example, 3 μm or more and 10 μm or less. In FIG. 5A-5N, it is not intended to illustrate exact ratios of thicknesses of the structural elements.

In the example of FIG. 5A, the metal foil 11 is provided on both one surface (6a) and the other surface (6b), which is on the opposite side of the one surface (6a), of the base plate 6. Laminates 10 (see FIG. 3) can be respectively simultaneously formed on both front and back sides of the base plate 6. The printed wiring board (1a) can be efficiently manufactured. However, the metal foil 11 is not necessarily required to be provided on both front and back sides of the base plate 6. In FIGS. 5B-5J and the following description, illustration and description with respect to the other surface (6b) side of the base plate 6 are omitted. Further, in FIG. 5B-5J, only one laminate 10 on the one surface (6a) side of the base plate 6 is illustrated. However, it is also possible that multiple laminates 10 are respectively formed on the one surface (6a) side and the other surface (6b) side of the base plate 6.

In the method for manufacturing the printed wiring board of the embodiment, the laminate 10 is formed from the fourth conductor layer (2d) side. First, as illustrated in FIG. 5B, a plating resist layer 41 for forming the fourth conductor layer (2d) is formed on the metal foil 11. In the plating resist 41, openings (41b) are respectively formed in formation regions of the conductor patterns of the fourth conductor layer (2d), for example, using a photolithography technology. Then, by electrolytic plating using the metal foil 11 as a seed layer, a conductor film is formed in each of the openings (41b). When the printed wiring board (1a) of FIG. 3 is manufactured, as illustrated in FIG. 5B, the multiple second and third conductor pads (22, 23) and the wiring patterns 24 are formed in the multiple openings (41b) (when the printed wiring board 1 illustrated in FIG. 1 is manufactured, the third conductor pads 23 and the wiring patterns 24 are not formed). The third conductor pads 23 are formed on the metal foil 11 on an outer peripheral side of the second conductor pads 22. The fourth conductor layer (2d) including the predetermined conductor patterns such as the second conductor pads 22 is formed on the metal foil 11 from the conductor films in the openings (41b). Since etching is not used, the second conductor pads 22 and the like can be formed at a fine pitch in the fourth conductor layer (2d). It is also possible that the fourth conductor layer (2d) is formed using electroless plating. The fourth conductor layer (2d) is preferably formed of the same material as the metal foil 11.

In the example of FIG. 5B, an upper surface (2da) (surface on the opposite side of the metal foil 11) of the fourth conductor layer (2d) is substantially coplanar with an upper surface (41a) (surface on the opposite side of the metal foil 11) of the plating resist layer 41. In a subsequent process, the third resin insulating layer (3c) (see FIG. 5C) having a uniform thickness can be formed. After the formation of the fourth conductor layer (2d), when a height of the upper surface (2da) of the fourth conductor layer (2d) and a height of the upper surface (41a) of the plating resist layer 41 are different from each other, the upper surface (2da) of the fourth conductor layer (2d), or the upper surface (41a) of the plating resist layer 41, or both of the two, may be polished by sand blasting. By polishing, the two can be substantially coplanar with each other. However, as will be described later, the height of the upper surface (2da) of the fourth conductor layer (2d) and the height of the upper surface (41a) of the plating resist layer 41 may remain different from each other.

As illustrated in FIG. 5C-5G, the laminate 10 is formed by alternately laminating the resin insulating layers and the conductor layers on the fourth conductor layer (2d). In the method for manufacturing the printed wiring board of the embodiment, without removing the plating resist layer 41, a resin insulating layer of the laminate 10 is formed on the fourth conductor layer (2d). That is, as illustrated in FIG. 5C, the third resin insulating layer (3c) that forms the second surface (10S) of the laminate 10 is formed on the upper surface (2da) of the fourth conductor layer (2d) and on the upper surface (41a) of the plating resist layer 41. The third resin insulating layer (3c) is formed, for example, by thermocompression bonding a film-like epoxy resin or the like on the fourth conductor layer (2d) and on plating resist layer 41. Since side surfaces of the conductor patterns of the fourth conductor layer (2d) are not covered by the third resin insulating layer (3c), at completion, the second and third conductor pads (22, 23) and the wiring patterns 24 are obtained protruding from the second surface (10S) of the laminate 10.

As illustrated in FIG. 5D, conduction holes (4ca) penetrating the third resin insulating layer (3c) are respectively formed at formation locations of the third via conductors (4c) (see FIG. 3). For example, CO2 laser is irradiated to predetermined positions on the third resin insulating layer (3c). By irradiating laser to the third resin insulating layer (3c) from the opposite side of the base plate 6, the conduction holes (4ca) are formed each having a tapered shape that is gradually reduced in diameter toward the second surface (l OS) side. Subsequently, a metal layer (2ca) is formed in the conduction holes (4ca) and on a surface of the third resin insulating layer (3c) by electroless plating or sputtering or the like.

As illustrated in FIG. 5E, an electrolytic plating film (2cb) is formed by electrolytic plating using the metal layer (2ca) as a seed layer. The electrolytic plating film (2cb) is formed using a so-called pattern plating method or the like using a plating resist (not illustrated in the drawings) that has openings of predetermined shapes at formation regions of the conductor patterns of the third conductor layer (2c) and at positions of the conduction holes (4ca). After the formation of the electrolytic plating film (2cb), the plating resist (not illustrated in the drawings) is removed. Then, exposed portions of the metal layer (2ca), which are exposed by the removal of the plating resist, are removed by etching. As a result, the third conductor layer (2c) is formed by the metal layer (2ca) on the third resin insulating layer (3c) and the electrolytic plating film (2cb) on the third resin insulating layer (3c) and on the conduction holes (4ca). Further, the third via conductors (4c) are formed by the metal layer (2ca) and the electrolytic plating film (2cb) in the conduction holes (4ca). The conduction holes (4ca) each have a tapered shape that is gradually reduced in diameter toward the second surface (10S) side. Therefore, along the shapes of the conduction holes (4ca), the third via conductors (4c) each having a shape that is gradually reduced in diameter toward the second surface (10S) side can be formed.

As illustrated in FIG. 5F, by repeating processes similar to the processes of FIG. 5C-5E, the second resin insulating layer (3b), the second conductor layer (2b), and the second via conductors (4b) are formed on the third conductor layer (2c) and the third resin insulating layer (3c), the second via conductors (4b) each having a shape that is gradually reduced in diameter toward the second surface (10S) side. In FIG. 5F, the third conductor layer (2c) and the second conductor layer (2b) are each simplified as one layer in the illustration. In FIG. 5G-5N, the conductor layers are also similarly simplified in the illustration.

Further, by repeating processes similar to the processes of FIG. 5C-5E, as illustrated in FIG. 5G, the first resin insulating layer (3a), the first conductor layer (2a) and the first via conductors (4a) are formed on the second resin insulating layer (3b) and the second conductor layer (2b), the first via conductors (4a) each having a shape that is gradually reduced in diameter toward the second surface (10S) side.

By the above formation of the conductor layers and the resin insulating layers, the laminate 10 is formed on the metal foil 11. The laminate 10 includes the fourth conductor layer (2d) formed on the metal foil 11, and has the second surface (10S) that is formed by the third resin insulating layer (3c) and is on the metal foil 11 side, and has the first surface (10F) that is formed by the first resin insulating layer (3a) and is on the opposite side of the second surface (10S). The multiple first conductor pads 21 are formed in the first conductor layer (2a) positioned on the most first surface (10F) side. The multiple first conductor pads 21 are formed protruding on the first surface (10F). When the printed wiring board (1a) has a different number of conductor layers from the laminate 10 illustrated in FIG. 3, the number of repetitions of the processes illustrated in FIG. 5C-5E is appropriately adjusted. For example, when a printed wiring board having only one resin insulating layer and conductor layers provided on both sides of the resin insulating layer is manufactured, the processes of FIG. 5C-5E are not repeated.

Materials for the first-fourth conductor layers (2a-2d) and the first-third via conductors (4a-4c) are not particularly limited as long as the materials have good conductivity and allow the first-fourth conductor layers (2a-2d) and the first-third via conductors (4a-4c) to be easily formed by plating and can be easily removed by etching. Examples of the materials for the conductor layers and the via conductors include copper, nickel and the like, and copper is preferably used. As described above, materials for the first-third resin insulating layers (3a-3c) are not particularly limited as long as the materials have good insulating properties and the like. In addition to the above-described epoxy resin, bismaleimide triazine resin (BT resin), phenol resin and the like can be used. A resin material that forms the resin insulating layers may contain inorganic filler such as silica.

As illustrated in FIG. 5H, the solder resist layer 5 having the openings (5a) on the first conductor pads 21 is formed. The solder resist layer 5 is formed on the surface of the first resin insulating layer (3a) exposed without being covered by the first conductor layer (2a) and on the outer edge portions of the first conductor pads 21. For example, a layer of a photosensitive epoxy resin is formed on the first conductor layer (2a) and on the first resin insulating layer (3a) by printing, spray coating or the like, and the openings (5a) are formed using a photolithography technology. An energization inspection of the laminate 10 may be performed before or after the formation of the solder resist layer 5. By performing the energization inspection, a defective product in the formation process of the laminate 10 can be removed. Waste of a support plate (to be described later), an electronic component, and man-hours due to that a defective product is transferred to a subsequent process is prevented.

As illustrated in FIG. 5I, the support plate 7 is provided on the first surface (10F) of the laminate 10 with the solder resist layer 5 sandwiched therebetween. The support plate 7 supports the laminate 10 after removal of the base plate 6 (to be described later). As described above, a glass epoxy board or the like is used for the support plate 7. The adhesive layer 8 having adequate adhesiveness (adhesion) with respect to the solder resist layer 5 is provided on a bonding surface of the support plate 7 and/or the solder resist layer 5. Due to the adhesiveness of the adhesive layer 8, the support plate 7 and the solder resist layer 5 are adhered to each other. When necessary, the adhesive layer 8 is cured by heating or the like.

As illustrated in FIG. 5J, the base plate 6 and the laminate 10 are separated from each other, and the base plate 6 is removed. Specifically, the carrier metal foil 12 bonded to the base plate 6 is separated from the metal foil 11. That is, the base plate 6 and the laminate 10 are separated from each other such that the metal foil 11 remains on the second surface (10S) of the laminate 10. For example, the thermoplastic adhesive that adheres the metal foil 11 and the carrier metal foil 12 to each other is softened by heating, and, in this state, the metal foil 11 and the carrier metal foil 12 are pulled apart. When the metal foil 11 and the carrier metal foil 12 are adhered to each other only in an outer peripheral portion, the metal foil 11 and the carrier metal foil 12 may be cut at an inner peripheral side of the adhering portion so that the adhering portion is removed. It is also possible to separate the base plate 6 and the laminate 10 from each other by simply pulling the two in mutually opposite directions. As illustrated in FIG. 5J, by the separation of the carrier metal foil 12 and the metal foil 11 from each other, the metal foil 11 is exposed on the second surface (10S) side of the laminate 10. The metal foil 11 exposed by being separated from the carrier metal foil 12 is removed by etching or the like.

As illustrated in FIG. 5K, due to the removal of the metal foil 11, surfaces of the conductor patterns, such as the second and third conductor pads (22, 23), of the fourth conductor layer (2d), together with the plating resist layer 41, are exposed. In order to reliably remove the metal foil 11, the etching process can be continued even after the metal foil 11 has substantially disappeared. When the fourth conductor layer (2d) is formed of a material that can be etched with an etching solution for the metal foil 11, the exposed surfaces of the conductor patterns of the fourth conductor layer (2d) can also be etched. Therefore, in the example illustrated in FIG. 5K, the surfaces (22a) of the second conductor pads 22 and the surfaces (23a) of the third conductor pads 23 are recessed relative to the exposed surface of the plating resist layer 41 on the opposite side of the support plate 7.

Subsequently, the plating resist layer 41 is removed, for example, using an amine-based solution. As illustrated in FIG. 5L, due to the removal of the plating resist layer 41, side surfaces of the second conductor pads 22 and the third conductor pads 23 that protrude on the second surface (10S) of the laminate 10 are exposed on the second surface (10S). Through the above processes, the printed wiring board (1a) illustrated in FIG. 3 is completed. Although not illustrated in the drawings, a surface protective film such as an OSP film may be formed on each of the second and third conductor pads (22, 23). Even during use of the printed wiring board (1a), when the side surfaces of the second and third conductor pads (22, 23) are not covered by solder or the like, the surface protective film effectively functions in terms of corrosion prevention.

In each of the drawings referenced in the above description about the method for manufacturing the printed wiring board of the embodiment, the upper surfaces (2da, 41a) (surfaces on the opposite side of the metal foil 11) of the fourth conductor layer (2d) and the plating resist layer 41 are substantially coplanar with each other (see FIG. 5B). However, it is also possible that the third resin insulating layer (3c) is formed on the fourth conductor layer (2d) in a state in which the upper surface (2da) of the fourth conductor layer (2d) and the upper surface (41a) of the plating resist layer 41 have different heights.

For example, it is also possible that the third resin insulating layer (3c) is formed in a state in which the upper surface (2da) of the fourth conductor layer (2d) is positioned on the metal foil 11 side of the upper surface (41a) of the plating resist layer 41. In this case, since the resin material of the third resin insulating layer (3c) can enter into the openings (41b) of the plating resist layer 41, an interface between the third resin insulating layer (3c) and the fourth conductor layer (2d) can protrude from the second surface (10S) of the laminate 10. The distance (S) between each of the surfaces (22a, 23a) of the second and third conductor pads (22, 23) and the second surface (10S) can be increased. Further, when the fourth conductor layer (2d) is formed by electrolytic plating as illustrated in FIG. 5B, in each opening (41b) of the plating resist layer 41, a formation speed of a conductor film is faster on a center side than on an inner wall side of the opening (41b). Therefore, the upper surface (2da) of the fourth conductor layer (2d) may become a curved surface that protrudes toward the opposite side of the metal foil 11. By forming the third resin insulating layer (3c) on the fourth conductor layer (2d) having such an upper surface (2da), the fourth conductor layer (2d) can be formed having a curved interface with the third resin insulating layer (3c), the curved interface protruding toward the third resin insulating layer (3c) side. Since a contact area between the fourth conductor layer (2d) and the third resin insulating layer (3c) is larger as compared to a case of a flat interface, adhesion strength between the fourth conductor layer (2d) and the third resin insulating layer (3c) is high.

Further, in the etching of the exposed surface of the fourth conductor layer (2d) after the etching of the metal foil 11 described with reference to FIG. 5K, in each opening (41b) of the plating resist layer 41, an etching speed is faster on a center than on an inner wall side of the opening (41b). Therefore, the surfaces (22a) of the second conductor pads 22 and the surfaces (23a) of the third conductor pads 23 can each have a curved shape that is recessed toward the second surface (10S) side of the laminate 10. For example, an electronic component or the like having bump-shaped electrodes can be stably placed on the surfaces (22a, 23a) of the second and third conductor pads (22, 23).

When the printed wiring board having an electronic component illustrated in FIG. 4 is manufactured, the electronic component (E1) is mounted on the printed wiring board (1a) illustrated in FIG. 5L. As illustrated in FIG. 5M, the electronic component (E1) is positioned on the second surface (10S) of the laminate 10 such that the conductive members (B1) are respectively positioned on the surfaces (22a) of the second conductor pads 22. Before the positioning of the electronic component (E1), a bonding material such as a solder paste may be supplied onto the second conductor pads 22. Together with the electronic component (E1), the printed wiring board (1a) is heated in a reflow furnace or a high temperature tank or the like, and the electronic component (E1) is connected to the second conductor pads 22. Since the electronic component (E1) is mounted in a state in which the laminate 10 is supported by the support plate 7, the electronic component (E1) can be properly mounted on the printed wiring board (1a). The printed wiring board having the electronic component (E1) illustrated in FIG. 4 is completed.

After the electronic component (E1) is mounted, as illustrated in FIG. 5N, the support plate 7 may be peeled off from the laminate 10. As a result, the first conductor pads 21 are exposed, and connection between an external electrical circuit and the first conductor pads 21 is facilitated. Further, as illustrated in FIG. 5N, a resin sealing layer (M) covering around the electronic component (E1) may be formed. In the case where the resin sealing layer (M) is formed, the support plate 7 may be peeled off before the formation of the resin sealing layer (M), or may be peeled off after the formation of the resin sealing layer (M).

As described above, the adhesive layer 8 that closely adheres the support plate 7 and the laminate 10 to each other is preferably formed of a material that does not have strong adhesion with the solder resist layer 5. In this case, the support plate 7 and the laminate 10 can be easily separated from each other by pulling the two in mutually opposite directions. Depending on adhesive properties of the adhesive layer 8, the support plate 7 and the laminate 10 may be separated from each other while ultraviolet irradiation or heating is performed, or after ultraviolet irradiation or heating is performed. After the electronic component (E1) is mounted, the support plate 7 can be removed, for example, at an appropriate timing up to a process of connecting the first conductor pads 21 and an external electrical circuit.

The resin sealing layer (M) can be formed, for example, by supplying a flowable mold resin mainly composed of an epoxy resin or the like to an upper surface and surrounding areas of the electronic component (E1) and applying heat when necessary. The resin sealing layer (M) may be formed using any other method such as laminating and heating a resin film on the electronic component (E1). Further, it is also possible that a so-called underfill-like resin sealing layer, which fills only a gap between the electronic component (E1) and the laminate 10, is formed.

Next, a printed wiring board of another embodiment of the present invention is described with reference to the drawings.

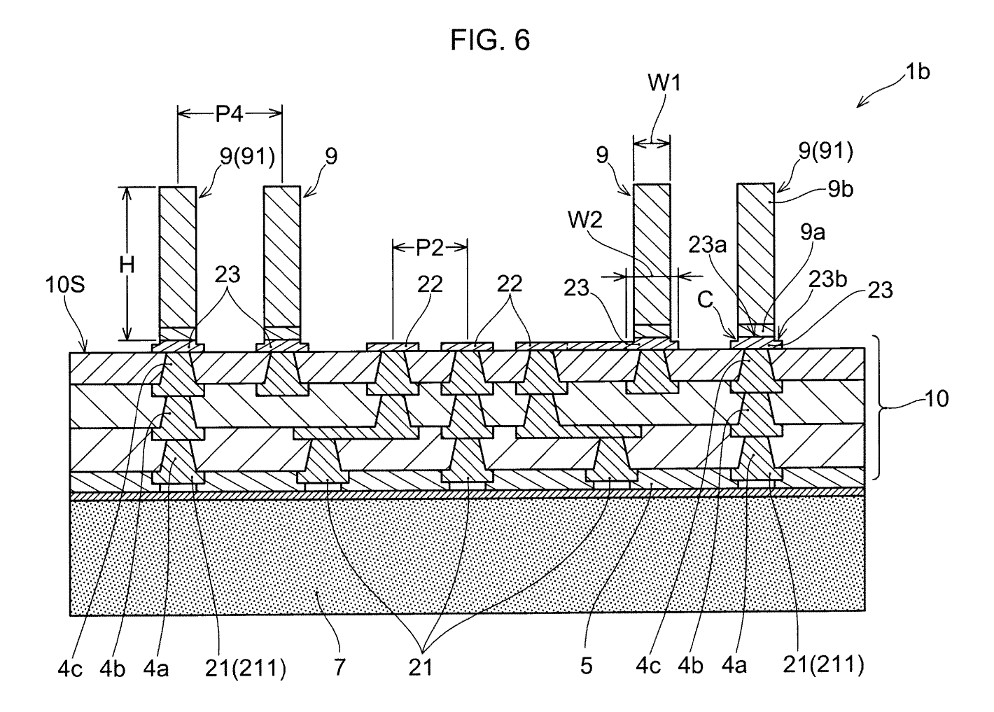

FIG. 6 illustrates a cross-sectional view of a printed wiring board (1b) of another embodiment. The printed wiring board (1b) of the present embodiment is different from the printed wiring board (1a) of FIG. 3 in that conductor posts 9 are provided. A structural element that is the same as in the printed wiring boards (1, 1a) of FIGS. 1 and 3 is indicated using the same reference numeral symbol as in FIGS. 1 and 3, and description about the structural element is omitted as appropriate.

As illustrated in FIG. 6, in the printed wiring board (1b), the conductor posts 9 are respectively formed on the surfaces (23a) of the multiple third conductor pads 23 on the opposite side of the second surface (10S) of the laminate 10. The conductor posts 9 are columnar bodies that are formed of a conductive material and each have an arbitrary bottom surface (end surface) shape. For example, an external electronic component or a wiring board (not illustrated in the drawings) is connected to end surfaces of the conductor posts 9 on the opposite side of the laminate 10. That is, the laminate 10 and an external electrical circuit (not illustrated in the drawings) can be connected to each other via the conductor posts 9.

The conductor posts 9 are each formed from a metal foil layer (9a) and a plating film layer (9b), the metal foil layer (9a) facing the laminate 10 and being in contact with a third conductor pad 23, and the plating film layer (9b) being formed on the metal foil layer (9a). The metal foil layer (9a) is formed of, for example, a metal foil such as a copper foil or a nickel foil. Examples of a material for the plating film layer (9b) include copper, nickel and the like, but are not limited to these. Preferably, the plating film layer (9b) is formed of an electrolytic copper plating film.

The conductor posts 9 can each be formed to have any height according to a required spacing between the laminate 10 and an external electronic component or the like (not illustrated in the drawings). The required spacing between the laminate 10 and an external electronic component or the like is defined, for example, according to a thickness of an electronic component to be mounted on the second conductor pads 22. For example, a height (H) of each of the conductor posts 9 is 50 μm or more and 200 μm or less. A relatively thick electronic component can be mounted on the second conductor pads 22. Further, the conductor posts 9 can be formed within a relatively short time by electrolytic plating or the like. The height (H) of each of the conductor posts 9 is a distance from an interface between a conductor post 9 and a third conductor pad 23 to a front end surface of the conductor post 9.

The multiple conductor posts 9 have an array pitch (P4). For example, the array pitch (P4) of the conductor posts 9 is substantially the same as the array pitch of the third conductor pads 23. In the example of FIG. 6, the array pitch (P4) of the conductor posts 9 is larger than the array pitch (P2) of the second conductor pads 22.

The conductor posts 9 are connected to predetermined conductor patterns in the laminate via the third conductor pads 23. The conductor posts 9 can be connected to any conductor pads or wiring patterns in any conductor layer in the laminate 10. In the printed wiring board (1b) of FIG. 6, in the drawing, a left-right direction outer side conductor post 91 and a first conductor pad 211 among the multiple first conductor pads 21 are formed at overlapping positions in a plan view, and are connected to each other. The laminate 10 has first-third via conductors (4a, 4b, 4c) that are formed at positions overlapping with the conductor post 91 in a plan view. The conductor post 91 is connected to the first conductor pad 211 via the third via conductor (4c), the second via conductor (4b) and the first via conductor (4a) that are formed at overlapping positions in a plan view. That is, the conductor post 91 and the first conductor pad 211 are connected to each other via a so-called stack via. In particular, in the example of FIG. 6, the first conductor pad 211, the first-third via conductors (4a, 4b, 4c), the third conductor pad 23 and the conductor post 91 are substantially coaxially formed. The conductor post 91 and the first conductor pad 211 can be connected to each other without requiring a lot of area in the conductor layers in the laminate 10. The term “plan view” refers to a way of viewing the printed wiring board (1b) from outside, and means to view the printed wiring board (1b) along a direction parallel to a thickness direction of the printed wiring board (1b).

The conductor posts 9 each have a width (W1) smaller than a width (W2) of each of the third conductor pads 23. Even when there are some variations in formation positions of the plating film layers (9b), the conductor posts 9 are less likely to protrude from the third conductor pads 23. All of the conductor posts 9 are respectively reliably formed on the third conductor pads 23. For example, a ration (W1/W2) of the width of each of the conductor posts 9 to the width of each of the third conductor pads 23 is 0.6 or more and 0.8 or less. A large margin region does not occur in each of the third conductor pads 23, and all of the conductor posts 9 can be respectively reliably formed on the third conductor pads 23. The width of each of the conductor posts 9 is a longest distance between any two points on an outer circumference of the bottom surface (end surface) of each of the conductor posts 9, and the width of each of the third conductor pads 23 is a longest distance between any two points on an outer circumference of the surface (23a) of each of the third conductor pads 23. For example, when the conductor posts 9 are each a cylindrical body, the width of each of the conductor posts 9 is a diameter of the bottom surface of each of the conductor posts 9.

Since the width (W1) of each of the conductor posts 9 is smaller than the width (W2) of each of the third conductor pads 23, an upper surface (23b) (surface on a conductor post 9 side) of an outer edge portion of each of the third conductor pads 23 is not covered by a conductor post 9 and is exposed. The upper surface (23b) of the outer edge portion of a third conductor pad 23 is positioned closer to the second surface (10S) of the laminate 10 than an interface between the third conductor pad 23 and the conductor post 9 (that is, the surface (23a) of the third conductor pad 23) is. That is, the third conductor pads 23 each have a height difference, on a surface on a conductor post 9 side, between the surface (23a) (which is an upper surface of a central portion) and the upper surface (23b) of the outer edge portion. When a force in a direction crossing the thickness direction of the printed wiring board (1b) is applied to the conductor posts 9, a stress is likely to concentrate on a corner part (C) that is a width transition point of a third conductor pad 23. The corner part (C) exists in each of the integrally formed third conductor pads 23. Therefore, strength against a stress in a vicinity of the corner part (C) is higher than that in a vicinity of an interface between a third conductor pad 23 and a conductor post 9. Reliability of the printed wiring board (1b) is high.

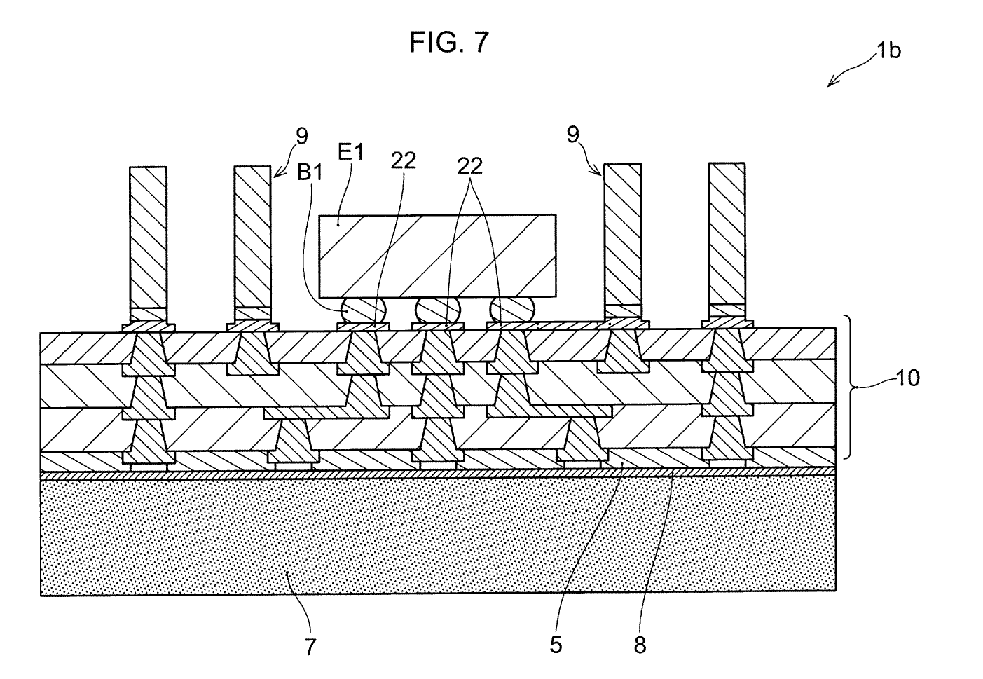

For example, similar to the example of FIG. 4, the electronic component (E1) is connected via the conductive members (B1) to the second conductor pads 22 of the printed wiring board (1b) of FIG. 6. As illustrated in FIG. 7, the printed wiring board (1b) having the electronic component (E1) mounted on the second conductor pads 22 can be formed. Then, for example, by connecting an external electronic component such as a semiconductor device to the front end surfaces of the conductor posts 9, an electronic component of a packaged-on-package type including two hierarchically mounted semiconductor devices can be obtained.

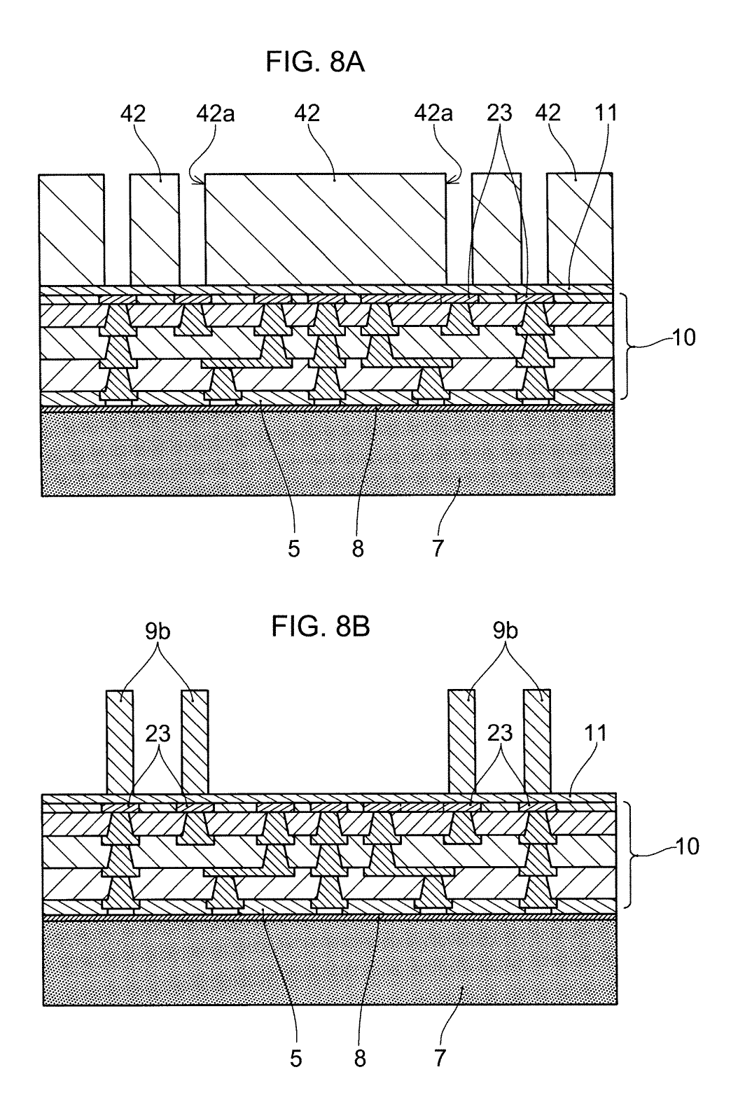

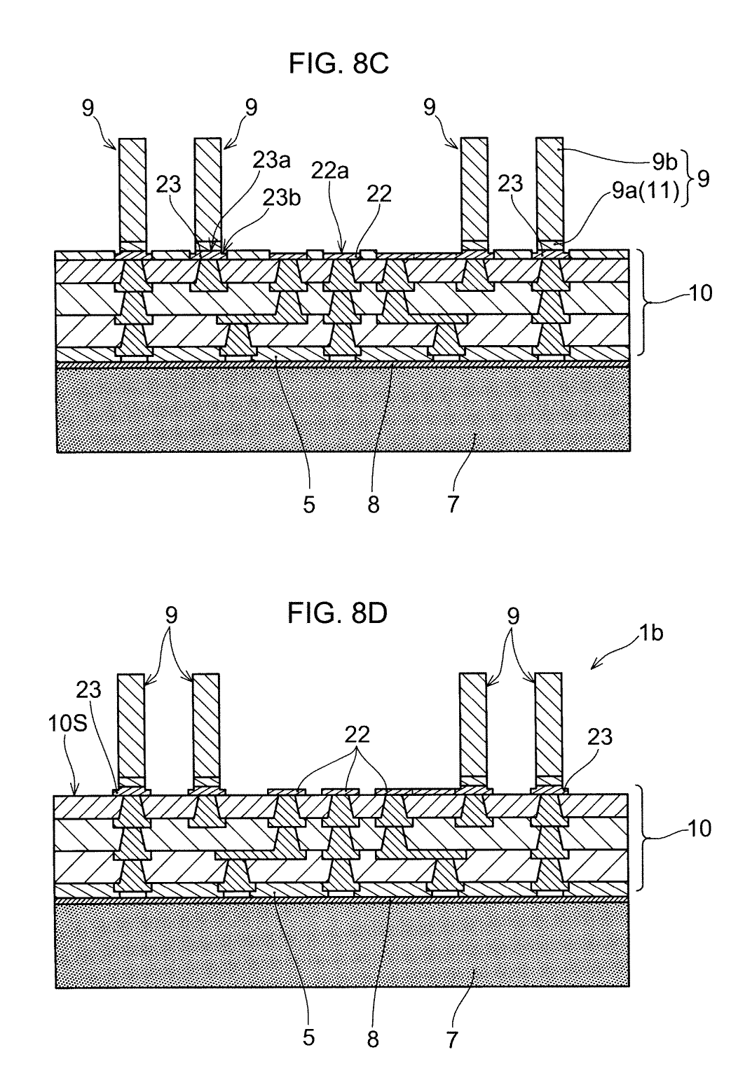

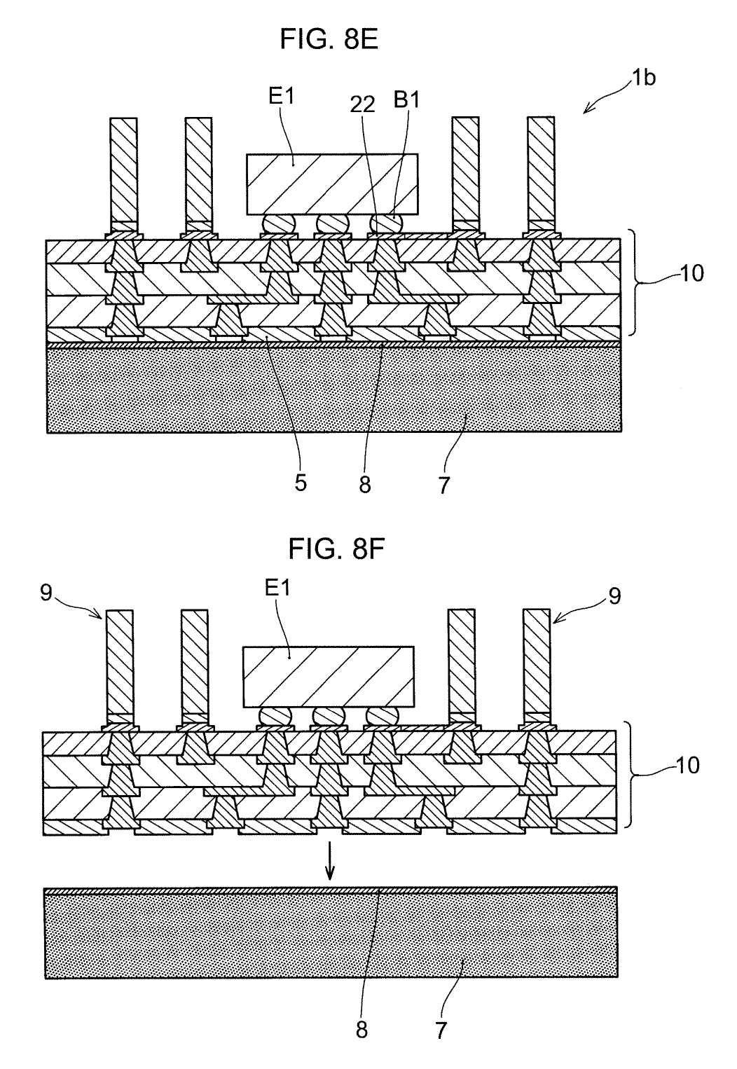

Next, an example of a method for manufacturing the printed wiring board (1b) of the other embodiment illustrated in FIGS. 6 and 7 is described with reference to FIG. 8A-8F. First, through the same processes as those illustrated in FIG. 5A-5J, the laminate 10 and the solder resist layer 5 are formed, the support plate 7 is provided, and the base plate 6 is removed. Then, in the case where the printed wiring board (1b) is manufactured, the conductor posts 9 (see FIG. 6) are formed before the removal of the metal foil 11.

As illustrated in FIG. 8A, a plating resist 42 for forming the conductor posts is formed on a surface of the metal foil 11 exposed due to the removal of the base plate 6. Openings (42a) are provided in the plating resist 42 at formation positions of the conductor posts 9, that is, on the third conductor pads 23, for example, using a photolithography technology. Since the width of each of the conductor posts 9 is smaller than the width of each of the third conductor pads 23 in the printed wiring board (1b) of FIG. 6, the openings (42a) are formed to each have an opening width smaller than the width of each of the third conductor pads 23. Subsequently, a plating film is formed in each of the openings (42a) by electrolytic plating using the metal foil 11 as a seed layer, and thereafter, the plating resist 42 is removed. As illustrated in FIG. 8B, the plating film layers (9b) that are respectively formed from the plating films in the openings (42a), are respectively formed on the third conductor pads 23 with the metal foil 11 sandwiched therebetween. The plating film layers (9b) each have a width smaller than the width of each of the third conductor pads 23.

As illustrated in FIG. 8C, a portion of the metal foil 11 that is exposed without being covered by the plating film layers (9b) is removed by etching. Portions of the metal foil 11 that are respectively covered by the plating film layers (9b) are not removed and respectively remain between the third conductor pads 23 and the plating film layers (9b). The conductor posts 9 are formed from the metal foil layers (9a), which are the remaining portions of the metal foil 11, and the plating film layers (9b).

Similar to the above-described process illustrated in FIG. 5K, when the fourth conductor layer (2d) is formed of a material that can be etched with an etching solution for the metal foil 11, the exposed surfaces of the conductor patterns of the fourth conductor layer (2d), which are exposed by the removal of the metal foil 11, can be etched. On the other hand, the surfaces (23a) of the third conductor pads 23 are respectively covered by the plating film layers (9b) and thus are not etched. However, the upper surfaces (23b) of the outer edge portions of the third conductor pads 23 are exposed by the removal of the metal foil 11, and thus are etched in the same manner as the surfaces (22a) of the second conductor pads 22. The outer edge portion of the third conductor pads 23 can be at least partially removed by etching from the upper surface (23b) side. As a result, the third conductor pads 23 are formed each having a height difference, on a surface on a conductor post 9 side, between the surface (23a) (which is an upper surface of a central portion) and the upper surface (23b) of the outer edge portion.

After the metal foil 11 is removed, the plating resist layer 41 is removed. As illustrated in FIG. 8D, due to the removal of the plating resist layer 41, the side surfaces of the second conductor pads 22 and the third conductor pads 23 that protrude on the second surface (10S) of the laminate 10 are exposed on the second surface (10S). Through the above processes, the printed wiring board (1b) illustrated in FIG. 6 is completed.

FIG. 8A-8D illustrate processes of forming the conductor posts 9 on one support plate 7. However, it is also possible that conductor posts 9 are substantially simultaneously formed on two support plates 7. For example, after the process (see FIG. 5I) of providing the support plate 7 on the laminate 10, and before or after the removal of the base plate 6 (see FIG. 5J), two support plates 7, on which two laminates 10 are respectively provided, are bonded to each other by a peelable adhesive or the like. The two support plates 7 are bonded to each other such that their exposed surfaces on opposite sides of the laminates 10 face each other. Then, the conductor posts 9 are substantially simultaneously formed on the third conductor pads 23 of the laminates 10 on the two bonded support plates 7 using the method described with reference to FIG. 8A-8D. The conductor posts 9 can be efficiently formed. The two support plates 7 are separated from each other after the conductor posts 9 are formed. As described above, in the case where two laminates 10 are respectively formed on both sides of the base plate 6, the support plates 7 of the two laminates 10 separated by removal of the base plate 6 may be bonded to each other.

When the printed wiring board having the electronic component (E1) illustrated in FIG. 7 is manufactured, as illustrated in FIG. 8E, the electronic component (E1) is mounted on the printed wiring board (1b). The electronic component (E1) is connected to the second conductor pads 22 via the conductive members (B1) using the same method as that described with reference to FIG. 5M, such as solder reflow. Then, as illustrated in FIG. 8F, the support plate 7 is peeled off from the laminate 10 as appropriate using the same method as that described with reference to FIG. 5N.

The printed wiring board of the embodiment is not limited to the structures illustrated in FIGS. 1, 3 and 6. For example, it is also possible that the array pitch (P2) of the second conductor pads 22 is the same as or larger than the array pitch (P3) of the third conductor pads 23. It is also possible that the first conductor layer (2a) and the fourth conductor layer (2d) include other conductor patterns in addition to the first-third conductor pads 21-23. It is also possible that the width (W1) of each of the conductor posts 9 is the same as or larger than the width (W2) of each of the third conductor pads 23. Further, it is also possible that a conductor post 9 other than a conductor post 91 (see FIG. 6) and a first conductor pad 21 other than a first conductor pad 211 (see FIG. 6) are connected to each other by a stack via. Conversely, it is also possible that a stack via connecting a conductor post 9 to a first conductor pad 21 is not formed at all. Further, it is also possible that the openings (5a) of the solder resist layer 5 each expose an entire first conductor pad 21. It is also possible that an opening (5a) that collectively expose the multiple first conductor pads 21 is formed in the solder resist layer 5. Further, the method for manufacturing the printed wiring board of the embodiment is not limited the method described with reference to FIGS. 5A-5N and FIGS. 8A-8F. For example, it is not necessarily required to continue the etching process after the removal of the metal foil 11. With respect to the method for manufacturing the printed wiring board of the embodiment, it is possible that a process other than the processes described above is added, and it is also possible that some of the processes described above are omitted.

A multilayer wiring board of Japanese Patent Laid-Open Publication No. 2009-224739 does not have a core substrate and is formed from only the thin wiring patterns and the insulating layer and the protective film that are mainly formed of resin, and warping is likely to occur during mounting of a semiconductor element or the like. It is likely to be difficult to stably mount a semiconductor element with good connection quality. Further, exposed surfaces of the wiring patterns on the connection surface side for external connection terminals are flush with a surface of the insulating layer in which the wiring patterns are embedded. Solder or the like supplied onto the wiring patterns is likely to wet spread. A short-circuit defect is likely to occur between adjacent wiring patterns. Further, via conductors that connect wiring patterns on both side of an insulating layer are each reduced in diameter from the mounting surface side for a semiconductor element toward the connection surface side for external connection terminals. Of each of the via conductors, an end surface on the mounting surface side for a semiconductor element is larger than an end surface on the connection surface side for external connection terminals. Therefore, on the mounting surface for a semiconductor element, when conductor pads are respectively provided on the via conductors at a fine pitch, gaps between the conductor pads are reduced. A short-circuit defect is likely to occur between the conductor pads.

A printed wiring board according to an embodiment of the present invention includes: a laminate of conductor layers and resin insulating layers, the laminate being formed by laminating at least one resin insulating layer and at least two conductor layers with the resin insulating layer sandwiched therebetween, the laminate having a first surface and a second surface that is on the opposite side of the first surface; a solder resist layer that is formed on the first surface of the laminate; and a support plate that is provided on the first surface of the laminate with the solder resist layer sandwiched therebetween. The laminate includes: multiple first conductor pads that are formed on the first surface; multiple second conductor pads that are formed on the second surface; and multiple via conductors that penetrate the resin insulating layers of the laminate. The multiple second conductor pads protrude on the second surface of the laminate. The multiple via conductors are each reduced in diameter from the first surface side toward the second surface side.

A method for manufacturing a printed wiring board according to an embodiment of the present invention includes: forming, on a metal foil provided on a base plate, a plating resist layer having multiple openings at predetermined positions; forming a conductor layer including multiple conductor pads on the metal foil by forming a conductor film in each of the multiple openings; forming a laminate of conductor layers and resin insulating layers, including at least one resin insulating layer, by laminating, on the conductor layer, at least one pair of a resin insulating layer and a conductor layer, the laminate having a second surface on the metal foil side and a first surface on the opposite side of the second surface; forming a solder resist layer on the first surface of the laminate; providing a support plate on the first surface of the laminate with the solder resist layer sandwiched therebetween; removing the base plate; and removing the metal foil. The resin insulating layer of the laminate is formed on surfaces of the conductor layer and the plating resist layer that are formed on the metal foil, the surfaces being on the opposite side of the metal foil. After the metal foil is removed, the plating resist layer that is exposed by the removal of the metal foil is removed.

According to an embodiment of the present invention, the conductor pads can be formed at a fine pitch while occurrence of a short-circuit defect can be suppressed. Further, due to the support plate, warpage or deflection of the printed wiring board is suppressed, and thus, an electronic component can be properly mounted.

Obviously, numerous modifications and variations of the present invention are possible in light of the above teachings. It is therefore to be understood that within the scope of the appended claims, the invention may be practiced otherwise than as specifically described herein.

1. A printed wiring board, comprising:
a support plate;
a laminate formed on the support plate and comprising a plurality of first conductor pads on a first surface side of the laminate and a plurality of second conductor pads on a second surface side of the laminate; and
a solder resist layer interposed between the support plate and the laminate and having a plurality of openings formed such that the openings are exposing the first conductor pads respectively,
wherein the laminate includes a resin insulating layer and has a first surface on the first surface side and a second surface on the second surface side on an opposite side with respect to the first surface of the laminate, and a via conductor structure penetrating from the first surface to the second surface of the laminate such that the via conductor structure comprises a plurality of via conductors formed in the resin insulating layer and tapering from the first surface side toward the second surface side of the laminate, and the plurality of second conductor pads is protruding from the second surface of the laminate respectively.

2. A printed wiring board according to claim 1, wherein the plurality of second conductor pads is formed such that the second conductor pads have surfaces formed at a height in a range of 5 μm to 30 μm from the second surface of the laminate.

3. A printed wiring board according to claim 1, wherein the plurality of first conductor pads is formed on the first surface of the laminate.

4. A printed wiring board according to claim 1, wherein the second surface of the laminate is not covered with a solder resist layer.

5. A printed wiring board according to claim 1, further comprising:
an electronic component connected to the plurality of second conductor pads such that the electronic component is mounted on the second surface side of the laminate.

6. A printed wiring board according to claim 1, wherein the plurality of second conductor pads is formed on a center side of the second surface of the laminate, and the laminate includes a plurality of third conductor pads formed on the second surface side of the laminate such that the third conductor pads are positioned on an outer peripheral side than the plurality of second conductor pads and protruding substantially a same height as the second conductor pads from the second surface of the laminate respectively.

7. A printed wiring board according to claim 6, wherein the plurality of second conductor pads is formed such that the plurality of second conductor pads has a pitch that is smaller than a pitch of the plurality of third conductor pads.

8. A printed wiring board according to claim 6, wherein the laminate includes a wiring pattern formed on the second surface side of the laminate such that the wiring pattern is protruding from the second surface of the laminate and connecting at least one of the second conductor pads and at least one of the third conductor pads.

9. A printed wiring board according to claim 6, further comprising:
a plurality of conductor posts formed on the second surface side of the laminate such that the conductor posts are formed on the third conductor pads respectively.

10. A printed wiring board according to claim 9, wherein the plurality of conductor posts is formed such that the plurality of conductor posts has a width that is smaller than a width of the plurality of third conductor pads.

11. A printed wiring board according to claim 9, wherein the conductor posts comprise metal film layer portions formed in contact with the third conductor pads and plating layer portions formed on the metal film layer portions respectively.

12. A printed wiring board according to claim 9, wherein the plurality of conductor posts has a height in a range of 50 μm to 200 μm.

13. A printed wiring board according to claim 9, wherein the laminate includes a via conductor structure penetrating from the first surface to the second surface of the laminate such that the via conductor structure, one of the conductor posts and one of the first conductor pads are formed in overlapping positions and that the via conductor structure is connecting the one of the conductor posts and the one of the first conductor pads.

14. A printed wiring board according to claim 2, wherein the plurality of first conductor pads is formed on the first surface of the laminate.

15. A method for manufacturing a printed wiring board, comprising:
forming a plating resist layer on a metal foil provided on a base plate such that the plating resist layer has a plurality of openings positioned for a plurality of conductor pads;
forming a conductor film in the openings of the plating resist such that a conductor layer comprising the plurality of conductor pads is formed on the metal foil;
laminating, on the conductor layer, at least one set of a resin insulating layer and a conductor layer, such that a laminate comprising the conductor layers and resin insulating layer is formed to have a first surface and a second surface on a metal foil side on an opposite side with respect to the first surface;
forming a solder resist layer on the first surface of the laminate;
positioning a support plate on the first surface of the laminate such that the solder resist layer is interposed between the laminate and the support plate;
removing the base plate from the laminate;
removing the metal foil on the laminate such that the plating resist layer is exposed; and
removing the plating resist from the laminate.

16. A method for manufacturing a printed wiring board according to claim 15, further comprising:
connecting an electronic component to the plurality of conductor pads such that the electronic component is mounted on the second surface side of the laminate prior to the removing of the support plate.

17. A method for manufacturing a printed wiring board according to claim 15, further comprising:
polishing at least one of the plating resist layer and the conductor layer prior to laminating the resin insulating layer of the laminate.

18. A method for manufacturing a printed wiring board according to claim 15, further comprising:
forming a plurality of conductor posts on a group of the conductor pads,
wherein the forming of the conductor posts comprises applying plating on a portion of the metal foil remaining on the group of the conductor pads such that a plating film layer is formed on the portion of the metal foil remaining on each of the conductor pads in the group.

19. A method for manufacturing a printed wiring board according to claim 18, wherein the forming of the conductor posts comprises forming the plurality of conductor posts such that the plurality of conductor posts has a width that is smaller than a width of the group of conductor pads, and the removing of the metal foil includes exposing surfaces of the conductor pads in the group such that outer edge portions of the surfaces of the conductor pads in the group are partially removed respectively.

20. A method for manufacturing a printed wiring board according to claim 18, further comprising:
bonding, to the support plate, a second support plate on which a second laminate is formed after the positioning of the support plate on the laminate such that the support plate and the second support plate are bonded to each other on exposed surfaces on opposite sides with respect to the laminate and second laminate; and
separating the support plate and the second support plate after the removing of the metal foil,
wherein the forming of the conductor posts comprises forming a plurality of conductor posts on a plurality of third conductor pads on the second laminate substantially simultaneously in a same process.
